(19) United States
(12) Patent Application Publication
(10) Pub. No.: US 2022/0285485 A1
(43) Pub. Date: Sep. 8, 2022

(54) SCHOTTKY BARRIER DIODE AND METHOD FOR MANUFACTURING THE SAME

(71) Applicants: HYUNDAI MOTOR COMPANY, Seoul (KR); KIA CORPORATION, Seoul (KR)

(72) Inventors: Dae Hwan Chun, Suwon-si (KR); Junghee Park, Suwon-si (KR); Jungyeop Hong, Seoul (KR); Youngkyun Jung, Seoul (KR); NackYong Joo, Suwon-si (KR)

(73) Assignees: HYUNDAI MOTOR COMPANY, Seoul (KR); KIA CORPORATION, Seoul (KR)

(21) Appl. No.: 17/317,576

(22) Filed: May 11, 2021

(30) Foreign Application Priority Data
Mar. 4, 2021 (KR) 10-2021-0028699

(51) Int. Cl. H01L 29/06; H01L 29/872; H01L 29/66

(52) U.S. Cl. CPC H01L 29/0619; H01L 29/872; H01L 29/6606; H01L 29/1608

(57) ABSTRACT

A Schottky barrier diode is provided. The Schottky barrier diode includes: an n+ type of substrate, an n− type of epitaxy layer disposed on a first surface of the n+ type of substrate and having a trench opened to an opposite side of a surface facing the substrate, a p type of region disposed on a side surface of the trench, a Schottky electrode disposed on the n− type of epitaxy layer and within the trench, and an ohmic electrode disposed on a second surface of the n+ type of substrate.

### CROSS-REFERENCE TO RELATED APPLICATION

This application claims priority to and the benefit of Korean Patent Application No. 10-2021-0028699 filed on Mar. 4, 2021, the entire contents of which are incorporated herein by reference.

### TECHNICAL FIELD

The present disclosure relates to a Schottky barrier diode and a manufacturing method thereof.

### BACKGROUND

Power semiconductor elements (devices) require low on-resistance or low saturation voltage to reduce power loss in conduction while allowing a very large current to flow. In addition, a characteristic capable of withstanding a reverse direction high voltage applied to both ends of the power semiconductor element, that is, a high breakdown voltage characteristic, is basically required at a moment of off-state or switch-off.

Depending on a rated voltage required by a power system, a concentration and thickness of an epitaxy layer region or drift region of a raw material for manufacturing the power semiconductor element are determined. According to the Poisson equation, as a high breakdown voltage is required, a drift region having a low concentration and a thick thickness is required, but this increases on-resistance and decreases a forward current density. A structure of the power semiconductor element should be designed so as to overcome such a trade-off relationship as much as possible.

Recently, the need for a power semiconductor element having a high breakdown voltage, a high current, and a high-speed switching characteristic has emerged in accordance with a trend of increasing a size and capacity of application devices. A silicon carbide (SiC) power element has excellent characteristics compared with the conventional silicon (Si) element, so that it may satisfy the above-mentioned characteristics.

The above information disclosed in this Background section is only for enhancement of understanding of the background of the disclosure, and therefore it may contain information that does not form the prior art that is already known in this country to a person of ordinary skill in the art.

### SUMMARY

One form of the present disclosure provides a Schottky barrier diode that may reduce a leakage current due to concentration of an electric field at a lower end of a trench thereof while minimizing decrease of on-state resistance and increase of on-state resistance.

Another form of the present disclosure provides a manufacturing method of a Schottky barrier diode that may reduce on-state resistance and a leakage current without requiring a separate reticle.

Another form of the present disclosure provides a Schottky barrier diode, including: an n+ type of substrate; an n− type of epitaxy layer disposed on a first surface of the n+ type of substrate and having a trench opened to an opposite surface of a surface facing the substrate; a p type of region disposed on a side surface of the trench; a Schottky electrode disposed on the n− type of epitaxy layer and within the trench; and an ohmic electrode disposed on a second side of the n+ type of substrate.

The p type region may extend from the side surface of the trench to a bottom surface thereof to surround a corner at which the side surface and the bottom surface of the trench meet.

A distance between the p-type regions in the bottom surface of one trench may be shorter than or equal to a distance between the p-type regions disposed on the side surfaces of the trenches adjacent to each other.

The distance between the p-type regions in the bottom surface of one trench may be 100 length % or less compared with the distance between the p-type regions disposed on the side surfaces of the trenches adjacent to each other.

Another form of the present disclosure provides a manufacturing method of a Schottky barrier diode, including: forming an n− type of epitaxy layer on a first surface of an n+ type of substrate; etching the n− type of epitaxy layer to form a trench; forming a p type of region on a side surface of the trench; forming a Schottky electrode on the n− type of epitaxy layer and within the trench; and forming an ohmic electrode on a second surface of the n+ type of substrate.

The forming of the p type of region may be performed by using a tilt ion injection method.

The forming of the p type of region may include forming the p type of region up to a corner at which the side surface and a bottom surface of the trench meet.

The Schottky barrier diode in one form of the present disclosure may reduce a leakage current due to concentration of an electric field at a lower end of a trench thereof while minimizing a decrease in on-state resistance and an increase in on-resistance.

The manufacturing method of the Schottky barrier diode in another form of the present disclosure may reduce on-state resistance and a leakage current without requiring a separate reticle.

### DRAWINGS

FIG. 1 illustrates a cross-sectional view of a Schottky barrier diode in one form of the present disclosure.

FIG. 2 illustrates a cross-sectional view of a conventional junction barrier Schottky (JBS) diode.

FIG. 3 to FIG. 8 sequentially illustrate respective steps of a manufacturing method of a Schottky barrier diode in one form of the present disclosure.

FIG. 9 and FIG. 10 illustrate results of simulation of an on-state electron current density in the same voltage application state of Schottky barrier diodes manufactured in a comparative example and an example, respectively.

FIG. 11 illustrates a graph of results of simulation of electrical characteristics of Schottky barrier diodes respectively manufactured in a comparative example and an example.

FIG. 12 to FIG. 14 illustrate graphs of results of simulation of electrical characteristics according to a change in distance ratio of a p-type region of a Schottky barrier diode manufactured in an example.

### DETAILED DESCRIPTION

Advantages and features of the present disclosure and methods of accomplishing the same may be understood more readily by reference to the following detailed description of preferred forms and the accompanying drawings. However, this disclosure may be embodied in many different forms and is not to be construed as limited to some forms of the present disclosure. Unless otherwise defined, all terms (including technical and scientific terms) used herein have the same meaning as commonly understood by one of ordinary skill in the art. It will be further understood that terms, such as those defined in commonly used dictionaries, should be interpreted as having meanings that are consistent with their meaning in the context of the relevant art and the present disclosure, and will not be interpreted in an idealized or overly formal sense unless expressly so defined herein. Throughout the specification, unless explicitly described to the contrary, the word “comprise” and variations such as “comprises” or “comprising” will be understood to imply the inclusion of stated elements but not the exclusion of any other elements.

Further, as used herein, the singular forms “a”, “an”, and “the” are intended to include the plural forms as well, unless the context clearly indicates otherwise.

In the drawings, the thicknesses of layers, films, panels, regions, areas, etc., are exaggerated for clarity. Like reference numerals designate like elements throughout the specification.

It will be understood that when an element such as a layer, film, region, area or substrate is referred to as being “on” another element, it can be directly on the other element or intervening elements may also be present. In contrast, when an element is referred to as being “directly on” another element, there are no intervening elements present.

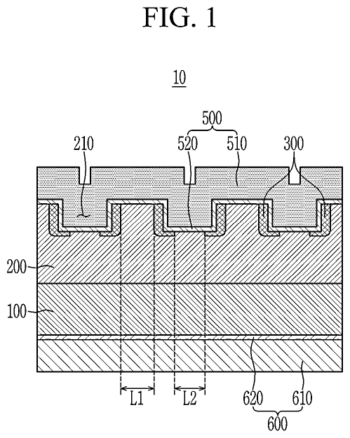

FIG. 1 illustrates a cross-sectional view of a Schottky barrier diode in some forms of the present disclosure.

Referring to FIG. 1, a Schottky barrier diode 10 includes an n+ type of substrate 100, an n− type of epitaxy layer 200, a p type of region 300, a Schottky electrode 500, and an ohmic electrode 600.

In the Schottky barrier diode 10, by applying a forward direction voltage (a positive potential at the Schottky electrode 500 side) between the Schottky electrode 500 and the ohmic electrode 600, an energy barrier at an interface between the Schottky electrode 500 and the n− type of epitaxy layer 200 from the n− type of epitaxy layer 200 is lowered, and a current flows from the Schottky electrode 500 to the ohmic electrode 600. Meanwhile, when a reverse direction voltage (a negative potential at the Schottky electrode 500 side) is applied between the Schottky electrode 500 and the ohmic electrode 600, a current does not flow due to a Schottky barrier.

Specifically, the n+ type of substrate 100 may be an n+ type of silicon carbide (SiC) substrate.

The n− type of epitaxy layer 200 is disposed on a first surface of the n+ type of substrate 100. The n− type of epitaxy layer 200 may include an n− type of silicon carbide (SiC). The n− type of epitaxy layer 200 may be, for example, an epitaxial layer epitaxially grown on the n+ type of substrate 100, which is an n+ type of silicon carbide substrate.

Optionally, an n type of epitaxy layer may be additionally positioned on the n− type of epitaxy layer 200. A doping concentration of the n type of epitaxy layer may be higher than that of the n− type of epitaxy layer 200.

The n− type of epitaxy layer 200 has a trench 210 that is opened to a surface opposite to a surface facing the n+ type of substrate 100. When the Schottky barrier diode 10 additionally includes the n type of epitaxy layer on the n− type of epitaxy layer 200, the trench 210 may be disposed on the n type of epitaxy layer, or may penetrate through the n type of epitaxy layer and be disposed on the n− type of epitaxy layer 200.

The p type of region 300 is disposed on a side surface of the trench 210. The p type of region 300 may be formed by injecting ions into the n− type of epitaxy layer 200 through the side surface of the trench 210.

That is, the Schottky barrier diode 10 has a junction barrier Schottky (JBS) type of structure that improves a leakage current reduction characteristic by forming the p type of region 300 at a lower end of the Schottky junction through an ion injection process. Accordingly, when a reverse voltage is applied, a leakage current is blocked and a breakdown voltage is improved, by overlapping of a depletion layer of a diffused pn diode.

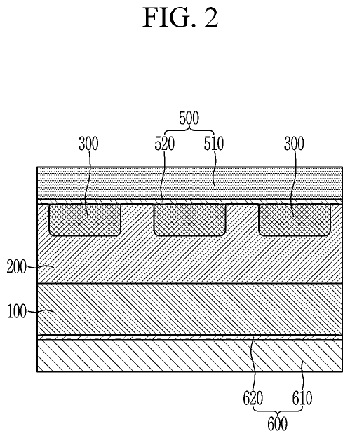

Meanwhile, FIG. 2 illustrates a cross-sectional view of a conventional junction barrier Schottky (JBS) diode, and referring to FIG. 2, the conventional junction barrier Schottky (JBS) diode has a structure in which the p type of regions 300 are formed at predetermined intervals in the n− type of epitaxy layer 200 to which the Schottky electrode 500 is bonded. However, since the p type of region 300 exists at the Schottky junction, a contact area between the Schottky electrode 500 and the n− type of epitaxy layer 200, which is a current path of the forward direction, is narrowed, and thus, when being electrically connected, an area through which a current may flow is narrowed, so that resistance increases. Consequently, there is a problem that the on-resistance of the diode is increased.

Meanwhile, in the Schottky barrier diode 10 in some forms of the present disclosure, the p type of region 300 is disposed on the side surface of the trench 210, so that the n− type of epitaxy layer 200 and the Schottky electrode 500 are bonded through a bottom surface of the trench 210 and an area between the trenches 210. Therefore, the contact area of the Schottky electrode 500 and the n− type of epitaxy layer 200 increases even while including the p type of region 300, and thus, a moving width of an electron current increases, so that it is possible to reduce the on-resistance of the Schottky barrier diode 10.

In addition, the p type of region 300 may extend from the side surface of the trench 210 to the bottom surface of the trench 210 to surround a corner at which the side surface and the bottom surface of the trench 210 meet. That is, the p type of region 300 may be entirely disposed on the side surface of the trench 210, and may be additionally disposed at a corner portion of the bottom surface of the trench 210. However, the p type of region 300 is not disposed on most of the bottom surface of the trench 210. This is because the contact area between the Schottky electrode 500 and the n− type of epitaxy layer 200 may be wider when the p type of region 300 is not disposed on the bottom surface of the trench 210.

According to this structure, the Schottky electrode 500 and the n− type of epitaxy layer 200 do not contact through a lower end edge of the trench 210 where an electric field may be concentrated, and an area of the n− type of epitaxy layer 200 adjacent to the bottom surface of the trench 210 may obtain a leakage current reduction effect as in the existing JBS structure due to overlapping of the depletion layer when an element is off.

In addition, a distance L2 between the p type of regions 300 in the bottom surface of one trench 210 may be shorter than or equal to a distance L1 between the p type of regions 300 disposed on the side surfaces of the trenches 210 adjacent to each other.

That is, the distance L2 between the p type of regions 300 in the bottom surface of one trench 210 represents an area in which the Schottky electrode 500 and the n− type of epitaxy layer 200 contact each other through the bottom surface of the trench 210, and the distance L1 between the p type of regions 300 disposed on the side surfaces of the trenches 210 adjacent to each other represents an area in which the Schottky electrode 500 and the n− type of epitaxy layer 200 contact each other through an upper area of the trench 210, that is, an area between adjacent trenches 210.

As an example, the distance L2 between the p type of regions in the bottom surface of one trench may be 100 length % or less compared with the distance L1 between the p type of regions disposed on the side surfaces of the trenches adjacent to each other, or it may be 90 length % or less, 80 length % or less, 70 length % or less, 60 length % or less, 50 length % or less, or it may be 10 length % or more, 20 length % or more, 30 length % or more, or 40 length % or more, or it may be 10 length % to 100 length %, 20 length % to 90 length %, 30 length % to 80 length %, or 40 length % to 70 length %.

Here, “length %” may be obtained by calculating L2/L1×100.

As a ratio of the distance L2 between the p type of regions 300 in the bottom of one trench 210 increases, on-state characteristics such as current density and on-resistance are improved, while off-state characteristics such as leakage current density and breakdown voltage deteriorate, and thus, a figure of merits (=breakdown voltage²/on-resistance) increases.

In addition, based on a position at which the length ratios of the distance L2 between the p type of regions 300 in the bottom of one trench 210 and the distance L1 between the p type of regions 300 disposed on the side surfaces of the adjacent trenches 210 is the same, as the length ratio of the distance L2 between the p type of regions 300 in the bottom surface of one trench 210 increases, the breakdown voltage does not decrease, but the leakage current density increases, and the increase of the current density and the decrease of the on-resistance become slow, and the increase of the figure of merits becomes slow. That is, the change in the on-off characteristic according to the continuous increase of the distance L2 between the p type of regions 300 in the bottom surface of one trench 210 becomes slow, so that electrical characteristic fluctuation according to a design change is insignificant.

The Schottky electrode 500 is disposed on the n− type of epitaxy layer 200 and in the trench 210, and it Schottky-contacts the n− type of epitaxy layer 200. The Schottky electrode 500 may include Cr, Pt, Pd, Au, Ni, Ag, Cu, Al, Mo, In, Ti, polycrystalline Si, an oxide thereof, a nitride thereof, or an alloy thereof. In addition, the Schottky electrode 500 may be multi-layered electrodes 510 and 520 having a structure in which different metal films are stacked, and for example, may include Pt/Au, Pt/Al, Pd/Au, Pd/Al, or Pt/Ti/Au, and Pd/Ti/Au.

As the Schottky electrode 500 is disposed even within the trench 210, the Schottky electrode 500 may include a groove opened to a surface opposite to a surface facing the trench 210 at a position corresponding to the trench 210.

The ohmic electrode 600 is disposed under the n+ type of substrate 100, and ohmic-contacts the n+ type of substrate 100. The ohmic electrode 600 may include Cr, Pt, Pd, Au, Ni, Ag, Cu, Al, Mo, In, Ti, polycrystalline Si, an oxide thereof, a nitride thereof, or an alloy thereof. In addition, the ohmic electrode 600 may include multi-layered electrodes 610 and 620 having a structure in which different metal films are stacked, for example, Ti/Au or Ti/Al. In this case, in order to reliably ohmic-contact the ohmic electrode 600 and the n+ type of substrate 100, the layer contacting the n+ type of substrate 100 of the ohmic electrode 600 may include Ti.

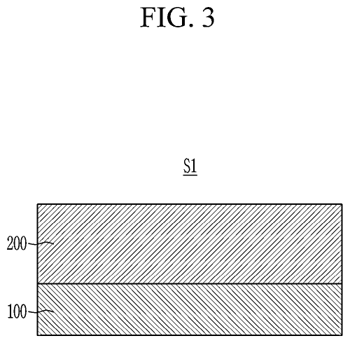

FIG. 3 to FIG. 8 sequentially illustrate respective steps of a manufacturing method of a Schottky barrier diode in some forms of the present disclosure. In FIG. 3 to FIG. 8, only main processes are shown, and their order may be changed according to process situations and conditions.

Referring to FIG. 3, the n+ type of substrate 100 is prepared, and the n− type of epitaxy layer 200 is formed on a first surface of the n+ type of substrate 100 by epitaxial growth (S1).

Alternatively, the n type of epitaxy layer may be formed on the n− type of epitaxy layer 200 by epitaxial growth. Here, the n type of epitaxy layer may be formed by injecting n ions into the n− type of epitaxy layer 200 rather than the epitaxial growth.

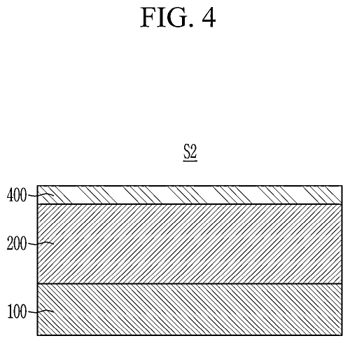

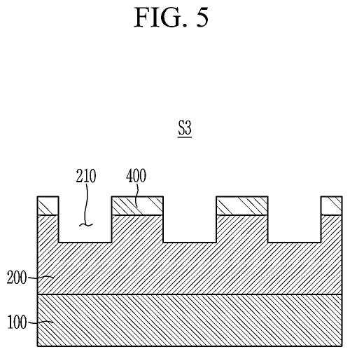

Referring to FIG. 4 and FIG. 5, after forming a mask 400 on the n− type of epitaxy layer 200 (S2), the plurality of trenches 210 are formed by etching the n− type of epitaxy layer 200 (S3).

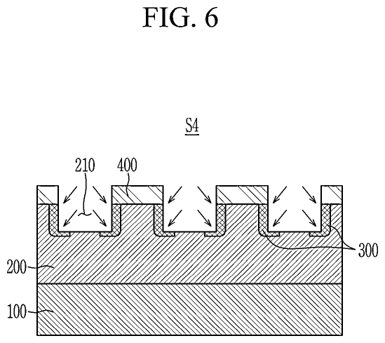

Referring to FIG. 6, the p type of region 300 is formed on the side surface of the trench 210 by using a tilt ion injection method. In this case, the p type of region 300 may be formed by injecting ions into a corner at which the side surface and the bottom surface of the trench 210 meet (S4).

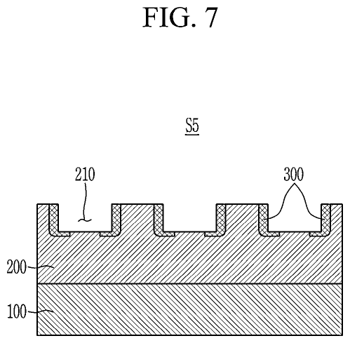

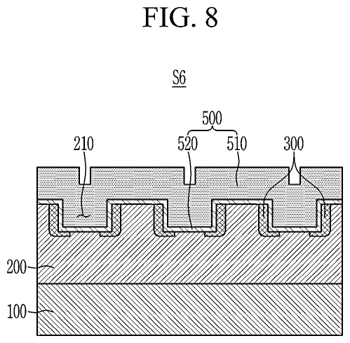

Referring to FIG. 7 and FIG. 8, after removing the mask 400 (S5), the Schottky electrode 500 is formed on the n− type of epitaxy layer 200 and in the trench 210 (S6).

Finally, the ohmic electrode 600 may be formed on a second surface of the n+ type of substrate 100 to manufacture the Schottky barrier diode 10 shown in FIG. 1.

Hereinafter, specific forms of the present disclosure are described. However, the following described examples are only for illustrating some forms of the present disclosure more specifically, and thus the scope of the disclosure should not be limited by these examples.

In the Schottky barrier diode, as shown in FIG. 1, after the trench 210 is formed, the p type of region 300 is formed to surround the side surface of the trench 210 and the corner at which the side surface and the bottom surface of the trench 210 meet.

In the Schottky barrier diode of a comparative example, the p type of regions 300 are formed at predetermined intervals in the n− type of epitaxy layer 200 without the trench 210 as shown in FIG. 2.

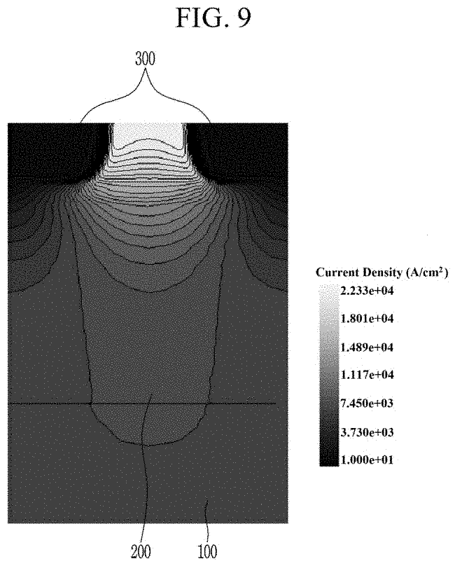

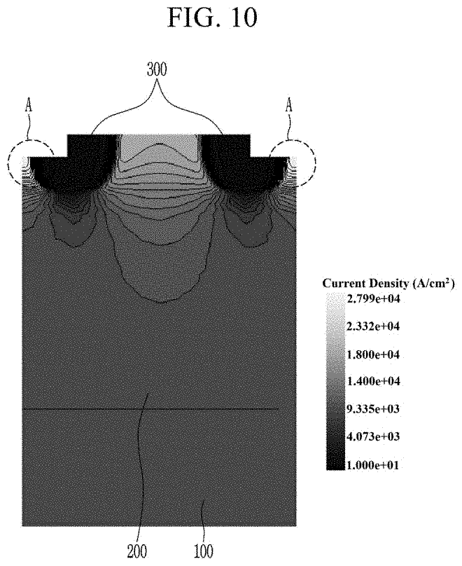

FIG. 9 and FIG. 10 illustrate results of simulation of an on-state electron current density in the same voltage application state of Schottky barrier diodes manufactured in a comparative example and an example, respectively.

Referring to FIG. 9 and FIG. 10, in the case of the Schottky barrier diode manufactured in the example, it can be seen that the electron current flows even on the Schottky junction surface at the lower end of the trench, and thus, it is possible to predict that the on-state resistance decreases and the current density increases. For reference, in FIG. 10, an area “A” represents an area in which the moving width of the electron current is increased.

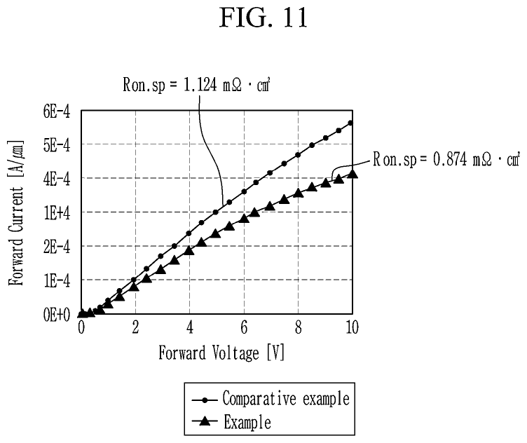

Table 1 and FIG. 11 show results of simulation of electrical characteristics of the Schottky barrier diodes respectively manufactured in the comparative example and the example.

TABLE 1

| | Breakdown | Current | | Figure |
|---|---|---|---|---|
| | voltage | density | On-resistance | of merits² |
| Classification | (V) | (A/cm²) | (mΩ · cm²) | (MW/cm²) |
| Comparative | 744 | 940 | 1.124 | 492 |
| example | | | | |
| Example¹ | 690 | 1216 | 0.874 | 545 |

¹Distance ratio between p type regions (L2/L1 × 100): 80 %
²Figure of merits = Breakdown voltage²/on-resistance

Referring to Table 1 and FIG. 11, compared with the Schottky barrier diode manufactured in the comparative example, the on-resistance of the Schottky barrier diode manufactured in the example decreases by 22% and the current density thereof increases by 29%. Accordingly, it can be seen that the Schottky barrier diode manufactured in the example may reduce the area of the element for flowing the same current by 23% as the current density increases, and the figure of merits of the element including both the breakdown voltage and on-resistance characteristics increases by 11%.

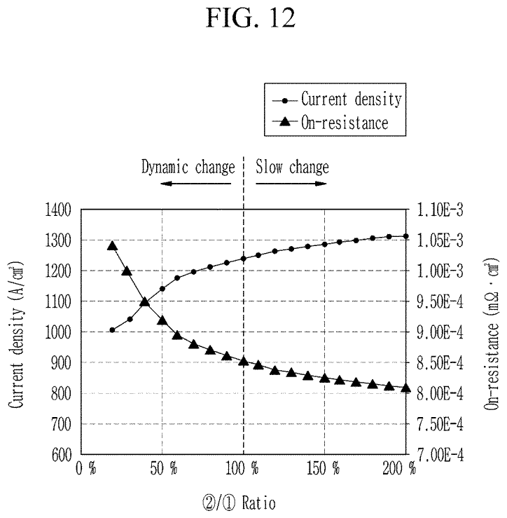

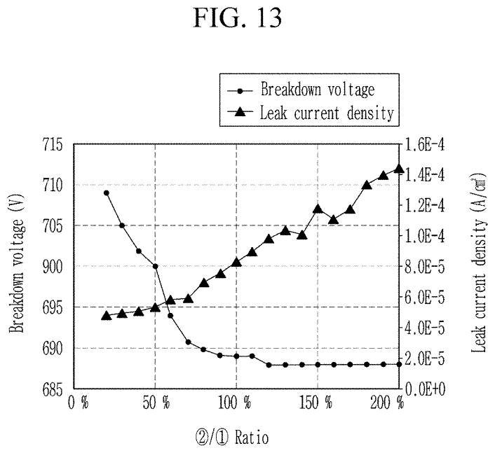

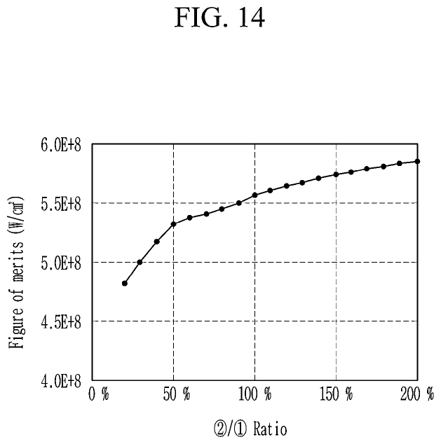

FIG. 12 to FIG. 14 illustrate graphs of results of simulation of electrical characteristics according to a change in distance ratio (L2/L1×100) of the p-type of region of the Schottky barrier diode manufactured in the example. Specifically, FIG. 12 illustrates an on-state simulation result, FIG. 13 illustrates an off-state simulation result, and FIG. 14 illustrates a calculation result of the figure of merits.

Referring to FIG. 12 to FIG. 14, it can be seen that as a ratio of the distance L2 between the p type of regions in the bottom of one trench increases, on-state characteristics such as current density and on-resistance are improved, while off-state characteristics such as leakage current density and breakdown voltage deteriorate, and thus, figure of merits (=breakdown voltage²/on-resistance) increases.

In addition, it can be seen that, based on a position at which the length ratios of the distance L2 between the p type of regions in the bottom of one trench and the distance L1 between the p type of regions disposed on the side surfaces of the adjacent trenches is the same, as the length ratio of the distance L2 between the p type of regions in the bottom surface of one trench increases, the breakdown voltage does not decrease, but the leakage current density increases, and the increase of the current density and the decrease of the on-resistance become slow, and the increase of the figure of merits becomes slow. That is, it can be seen that the change in the on-off characteristic according to the continuous increase of the distance L2 between the p type of regions in the bottom surface of one trench becomes slow, so that electrical characteristic fluctuation according to a design change is insignificant.

While this disclosure has been described in connection with what is presently considered to be practical forms, it is to be understood that the disclosure is not limited to the disclosed forms, but, on the contrary, is intended to cover various modifications and equivalent arrangements included within the spirit and scope of the appended claims.

### DESCRIPTION OF SYMBOLS

10: Schottky barrier diode
100: n+ type of substrate
200: n− type of epitaxy layer
210: trench
300: p type of region
400: mask
500: Schottky electrode
510, 520: multi-layered Schottky electrode
600: ohmic electrode
610, 620: multi-layered ohmic electrode

What is claimed is:

1. A Schottky barrier diode, comprising:
an n+ type of substrate;
an n− type of epitaxy layer disposed on a first surface of the n+ type of substrate and having a trench opened to an opposite side of a surface facing the substrate;
a p type of region disposed on a side surface of the trench;
a Schottky electrode disposed on the n− type of epitaxy layer and within the trench; and
an ohmic electrode disposed on a second surface of the n+ type of substrate.

2. The Schottky barrier diode of claim 1, wherein:
the p type of region extends from the side surface of the trench to a bottom surface of the trench to surround a corner at which the side surface and the bottom surface meet.

3. The Schottky barrier diode of claim 1, wherein:
a first distance between the p-type of regions in the bottom surface of the trench is shorter than or equal to a second distance between the p type of regions disposed on the side surfaces of the trenches adjacent to each other.

4. The Schottky barrier diode of claim 3, wherein:
the first distance divided by the second distance is a value equal to or less than 1.

5. A manufacturing method of a Schottky barrier diode, comprising:
forming an n− type of epitaxy layer on a first surface of an n+ type of substrate;
etching the n− type of epitaxy layer to form a trench;
forming a p type of region on a side surface of the trench;
forming a Schottky electrode on the n− type of epitaxy layer and within the trench; and
forming an ohmic electrode on a second surface of the n+ type of substrate.

6. The manufacturing method of the Schottky barrier diode of claim 5, wherein forming the p type of region comprises:
forming the p type of region by using a tilt ion injection.

7. The manufacturing method of the Schottky barrier diode of claim 5, wherein forming the p type of region comprises:
forming the p type of region up to a corner at which the side surface and a bottom surface of the trench meet.
